(19) United States
(12) Patent Application Publication
(10) Pub. No.: US 2016/0035994 A1
(43) Pub. Date: Feb. 4, 2016

(54) ORGANIC LIGHT EMITTING DEVICE

(71) Applicant: Industrial Technology Research Institute, Hsinchu (TW)

(72) Inventors: Chao-Feng SUNG, Hsinchu City (TW); Chih-Ming LAI, Changhua County (TW); Mei-Ju LEE, New Taipei City (TW); Yi-Ming CHANG, Hsinchu City (TW); Chen-Kun CHEN, Zhubei City (TW)

(21) Appl. No.: 14/447,103

(22) Filed: Jul. 30, 2014

(51) Int. Cl. H01L 51/50

(52) U.S. Cl. CPC H01L 51/5044; H01L 51/0085

(57) ABSTRACT

An organic light emitting device (OLED) is provided, may comprise a first organic electroluminescent cell, a second organic electroluminescent cell, a charge generation layer, disposed between the first and second organic electroluminescent cells, a first electrode and a second electrode formed at the first and second organic electroluminescent cells. The first organic electroluminescent cell comprises a fluorescent light emitting layer having a fluorescent emitting element and a phosphorescent light emitting layer having a phosphorescent emitting element. The second organic electroluminescent cell comprises at least one light emitting layer.

### TECHNICAL FIELD

The disclosure relates to an organic light emitting device.

### BACKGROUND

An organic light emitting device, also called an OLED, are attractive because of their low drive voltage, high luminance, wide viewing angle, and capability for full color flat emission displays and for other applications. Also, OLED is capable of providing the full spectrum light which is closest to natural lighting. With those properties, OLED has become increasingly interesting technology for lighting applications, among other applications.

Notwithstanding developments made in the OLED field, there are continuing needs for OLED devices that provide higher luminous efficiency or good color for illumination purposes, or both.

### SUMMARY

According to one embodiment, an organic light emitting device (OLED) is provided. The OLED comprises a first organic electroluminescent cell, a second organic electroluminescent cell, a charge generation layer, disposed between the first and second organic electroluminescent cells, a first electrode and a second electrode formed at the first and second organic electroluminescent cells. The first organic electroluminescent cell comprises a fluorescent light emitting layer having a fluorescent emitting element and a phosphorescent light emitting layer having a phosphorescent emitting element. The second organic electroluminescent cell comprises at least one light emitting layer.

According to another embodiment, an organic light emitting device (OLED) is provided. The OLED comprises a first organic electroluminescent cell, a second organic electroluminescent cell, a charge generation layer, disposed between the first and second organic electroluminescent cells, a first electrode and a second electrode formed at the first and second organic electroluminescent cells. The first organic electroluminescent cell comprises at least two light emitting layers emitting a first light with a first range of wavelengths, and a second light with a second range of wavelengths, wherein the first light has a main peak in a range of wavelengths substantially from 430 nm to 490 nm, and the second light has a main peak in a range of wavelengths substantially from 602 nm to 615 nm. The second organic electroluminescent cell comprises at least one light emitting layer emitting a third light with a third range of wavelengths, wherein the third light has a main peak in a range of wavelengths substantially from 520 nm to 550 nm.

According to a further embodiment, an organic light emitting device with color rendering index Ra larger than 80 is provided, comprising a first organic electroluminescent cell, a second organic electroluminescent cell, a charge generation layer, disposed between the first and second organic electroluminescent cells, a first electrode and a second electrode formed at the first and second organic electroluminescent cells. The first organic electroluminescent cell comprises a fluorescent light emitting layer having a fluorescent emitting element and a phosphorescent light emitting layer having a phosphorescent emitting element. The first organic electroluminescent cell has a first color temperature A and a color rendering index Ra larger than 40. The second organic electroluminescent cell comprises at least one light emitting layer, and has a second color temperature larger than (2X-A), wherein X is a target color temperature of the organic light emitting device. Also, an electroluminescence spectrum of the second organic electroluminescent cell is complementary to an electroluminescence spectrum of the first organic electroluminescent cell.

### BRIEF DESCRIPTION OF THE DRAWINGS

FIG. 1 illustrates a schematic cross-sectional view of an organic light emitting device according to the first embodiment of the disclosure.

FIG. 2 is a graph of electroluminescence spectra of the first organic electroluminescent cell, the second organic electroluminescent cell and the white OLED of the Example 1-1.

FIG. 3 is a graph of electroluminescence spectra of the first organic electroluminescent cell, the second organic electroluminescent cell and the white OLED of the Example 1-2.

FIG. 4 illustrates a schematic cross-sectional view of an organic light emitting device according to the second embodiment of the disclosure.

FIG. 5 is a graph of electroluminescence spectra of the first organic electroluminescent cell, the second organic electroluminescent cell and the white OLED of the Example 2-1.

FIG. 6 is a graph of electroluminescence spectra of the first organic electroluminescent cell, the second organic electroluminescent cell and the white OLED of the Example 2-2.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Below, exemplary embodiments of organic light emitting devices will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

The exemplary embodiments of the disclosure are directed to organic light emitting devices possessing good optical properties, such as high color rendering index, high luminous efficiency, or both.

According to the embodiment, an organic light emitting device at least comprises two organic electroluminescent cells connected by a charge generation layer, and one of the organic electroluminescent cells comprises two light emitting layers emitting lights with different colors while the other organic electroluminescent cell comprises at least one light emitting layer. According to the embodiment, a color light emission (ex: white light emission) with improved electroluminescent properties, such as high luminous efficiency and high color rendering index (CRI, defined by CIE) or general color rendering index (Ra), can be formed by spectra combination from the organic electroluminescent cells of the embodied organic light emitting device. In one embodiment, an OLED emitting white light, which is the combination of the complementary colored lights (such as the red light, the blue light and the yellow or green light) and possesses good optical properties such as high color rendering index and high luminous efficiency, can be obtained to meet the performance requirements of the lighting apparatus in the applications.

Embodiments are provided hereinafter with reference to the accompanying drawings for describing the related configurations and procedures, but the present disclosure is not limited thereto. It is noted that not all embodiments of the disclosure are shown. Structures of the embodiments would be different, and could be modified and changed optionally according to the design needs of the application. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

### First Embodiment

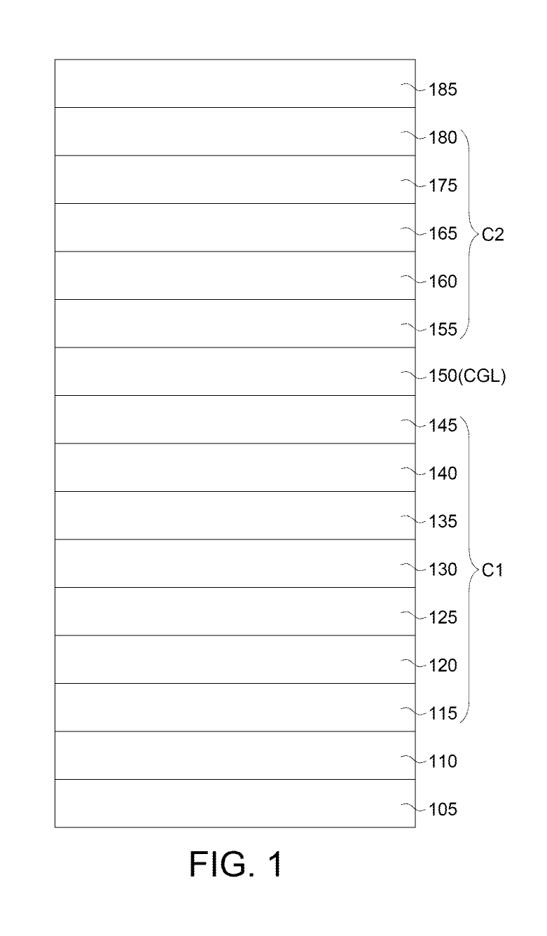

FIG. 1 illustrates a schematic cross-sectional view of an organic light emitting device according to the first embodiment of the disclosure. According to the first embodiment, an organic light emitting device comprising a first organic electroluminescent cell C1, a second organic electroluminescent cell C2 and a charge generation layer (CGL) 150 is disposed therebetween for connecting the first and second organic electroluminescent cells C1 and C2 are provided. The embodiment can be applied to form a tandem OLED. Also, a first electrode 110 and a second electrode 185 are formed at the first and second organic electroluminescent cells C1 and C2, respectively.

In the first embodiment, the first organic electroluminescent cell C1 comprises at least two light emitting layers emitting different colors of lights, i.e. first and second colors of lights, and the second organic electroluminescent cell C2 comprises at least one light emitting layer emitting a third color of light.

According to the embodiment, light emission with improved electroluminescent properties such as high luminous efficiency and high color rendering index (CRI, or general color rendering index Ra) can be obtained by the regime of spectra combination from the organic electroluminescent cells of the embodied organic light emitting device, so as to satisfy the color requirements of the practical application. In the first embodiment, an organic light emitting device with white light emission formed by spectra combination from the first and second organic electroluminescent cells C1 and C2 is exemplified for illustration.

According to one embodiment, one of the light emitting layers (ex: 125 and 135 of FIG. 1) of the first organic electroluminescent cell C1 is a fluorescent light emitting layer, and the other is a phosphorescent light emitting layer. The light emitting layer (ex: 165 of FIG. 1) of the second organic electroluminescent cell C2 could be a fluorescent light emitting layer or a phosphorescent light emitting layer. Hybrid fluorescent and phosphorescent light emitting layers in one of the organic electroluminescent cells (such as C1) at least increases the luminous efficiency of the organic light emitting device of the embodiment.

As shown in FIG. 1, the first organic electroluminescent cell C1 formed on the first electrode 110 may comprise a hole-injecting layer (HIL) 115, a hole-transporting layer (HTL) 120, a light emitting layer 125 emitting a first light with a first range of wavelengths, a carrier blocking layer 130, another light emitting layer 135 emitting a second light with a second range of wavelengths, an electron-transporting layer (ETL) 140, and an electron-injecting layer (EIL) 145 in series. In the first embodiment, the first range of wavelengths of the first light is different from the second range of wavelengths of the second light.

Similarly, the second organic electroluminescent cell C2, spaced apart from the first organic electroluminescent cell C1, may comprise a hole-injecting layer (HIL) 155, a hole-transporting layer (HTL) 160, a light emitting layer 165 emitting a third light with a third range of wavelengths, an electron-transporting layer (ETL) 175, and an electron-injecting layer (EIL) 180 in series. In the first embodiment, the third range of wavelengths of the third light is different from the first range of wavelengths of the first light, and is also different from the second range of wavelengths of the second light.

The organic light emitting device of the embodiment is typically provided over a supporting substrate 105 where either a cathode or an anode can be in contact with the substrate 105. The electrode in contact with the substrate 105 is typically referred to as the bottom electrode. In the first embodiment, the first electrode 110 is the anode and the second electrode 185 is the cathode; however, the present disclosure is not limited to that configuration. In the embodiment, at least one of the first electrode 110 and the second electrode 185 are transparent to enable the light transmission to the outside of the device.

Also, the substrate 105 can either be light transmissive or opaque, depending on the intended direction of light emission. The light transmissive property is for viewing the light emission through the substrate 105. Transparent glass or plastic is commonly employed in such cases. For example, if the light emission is viewed through the second electrode 185 (/top electrode), the transmissive characteristic of the bottom support is immaterial, and therefore can be light transmissive, light absorbing, or light reflective, wherein the substrate 105 for use in this case include, but are not limited to, glass, plastic, semiconductor materials, silicon, ceramics, and circuit board materials. In these device configurations, the second electrode 185 (/top electrode) is transparent to light.

In the embodiment, the HIL 115 facilitates the injection of holes from the first electrode 110 (ex: anode), and the HIL 155 facilitates the injection of holes from the hole generating side of a connecting unit (i.e. the CGL 150) into the adjacent HTL 160. The HTL 120 can be a layer comprising a large gap semiconductor that transports holes from the first electrode 110 (ex: anode), and the HTL 160 can be a layer comprising a large gap semiconductor that transports holes from the CGL 150 to the light emitting layer 165. The ETL 140 can be a layer comprising a large gap semiconductor capable of transporting electrons from a CGL 150 to the light emitting layers 125 and 135, and the ETL 175 can be a layer comprising a large gap semiconductor capable of transporting electrons from the second electrode 185 (ex: cathode) to the light emitting layer 165. The EIL 145 and the EIL 180 may comprise strong donor (ex: n-dopant) to provide lower voltage and high efficiency in the device. The EIL 180 is also a buffer layer providing protection against the deposition of the second electrode 185 (ex: cathode deposition).

In the embodiment, the CGL 150 disposed between the first organic electroluminescent cell C1 and the second organic electroluminescent cell C2 is used in conjunction with an electrode as inversion contact. Alternatively or in addition, in other embodiments, the CGL 150 can be used as a connecting unit that connects two adjacent organic electroluminescent cells in a stack. Generally, a CGL of the embodiment can have a number of different configurations and names, including, but not limited to, pn-junction, connecting unit, tunnel junction, etc. The disclosure has no particular limitation thereto.

According to the first embodiment, the light emitting layer 125 of the first organic electroluminescent cell C1 can be a fluorescent light emitting layer having a fluorescent emitting element emitting the first light, while the light emitting layer 135 can be a phosphorescent light emitting layer having a phosphorescent emitting element emitting the second light. The light emitting layer 165 of the second organic electroluminescent cell C2 may comprise a fluorescent emitting element or a phosphorescent emitting element. Hybrid fluorescent and phosphorescent light emitting layer 125 and 135 of the first organic electroluminescent cell C1 increases the luminous efficiency of the organic light emitting device of the embodiment.

In one embodiment of an organic light emitting device with high luminous efficiency, the light emitting layer 125 may comprise a fluorescent emitting element emitting blue light, the light emitting layer 135 may comprise a phosphorescent emitting element emitting red light, and the light emitting layer 165 may comprise another fluorescent or phosphorescent emitting element emitting yellow or green light, wherein the viewer can then perceive a white light from the organic light emitting device of the embodiment. The white light is the combination of the red light, the blue light and the yellow or green light.

Each of the light emitting layers of the OLED includes luminescent material(s) or phosphorescent material(s) where electroluminescence is produced as a result of electron-hole pair recombination in this region. Also, the light emitting layers can be comprised of a single material that more commonly include host material(s) doped with guest compound(s) or dopant(s) where light emission comes primarily from the dopant(s). The dopants are selected to produce colored light. Suitable host and dopant materials of respective light emitting layers for producing colored lights can be used for forming the light emitting layer. In one embodiment, the fluorescent emitting element (ex: in the light emitting layer 125) for emitting the blue light (having a main peak with the wavelength<500 nm) may be formed of, but not limited to, DSA-Ph, BCzVBi, BCzVB, or the like. The phosphorescent emitting element (ex: in the light emitting layer 165) for emitting the yellow or green light (500 nm<a main peak with the wavelength<600 nm) may be formed of, but not limited to, Ir(ppy)₃, (ppy)₂Ir(acac), Ir(dmppy)₃, Ir(chpy)₃, (Bt)₂Ir(acac), (t-bt)₂Ir(acac), or the like. The phosphorescent emitting element (ex: in the light emitting layer 135) for emitting the red light (a main peak with the wavelength<600 nm) may be formed of, but not limited to, (MDQ)₂Ir(acac), (DBQ)₂Ir(acac), Ir(pq)₂(acac), Ir(piq)₂(acac), or the like.

In one embodiment of an organic light emitting device with high Ra, the first light emitted from the light emitting layer 125 of the first organic electroluminescent cell C1 has a main peak in a range of wavelengths substantially from 430 nm to 490 nm (ex: blue light), the second light emitted from the light emitting layer 135 has a main peak in a range of wavelengths substantially from 602 nm to 615 nm (ex: red light), and the third light emitted from the light emitting layer 165 of the second organic electroluminescent cell C2 has a main peak in a range of wavelengths substantially from 520 nm to 550 nm (ex: yellow to green light).

Also, in one embodiment, a full width at half maximum (FWHM) of a main peak of the first light is larger than 55 nm, a FWHM of a main peak of the second light is equal to or larger than 65 nm, and a FWHM of a main peak of the third light is equal to or larger than 66 nm. Corporations of the adequate main peaks and FWHM values of the first, second and third lights contributes good color with high Ra for illumination. According to the embodiments, a color rendering index (such as Ra or CRI) of the light emitted from the organic light emitting device is larger than 80, and can be up to 90.

The following examples are included to provide additional guidance to those skilled in the art in practicing the disclosure. The examples provided are merely representative of the work that contributes to the teaching of the present application. Accordingly, these examples are not intended to limit the disclosure, as defined in the appended claims, in any manner.

### EXAMPLE 1-1

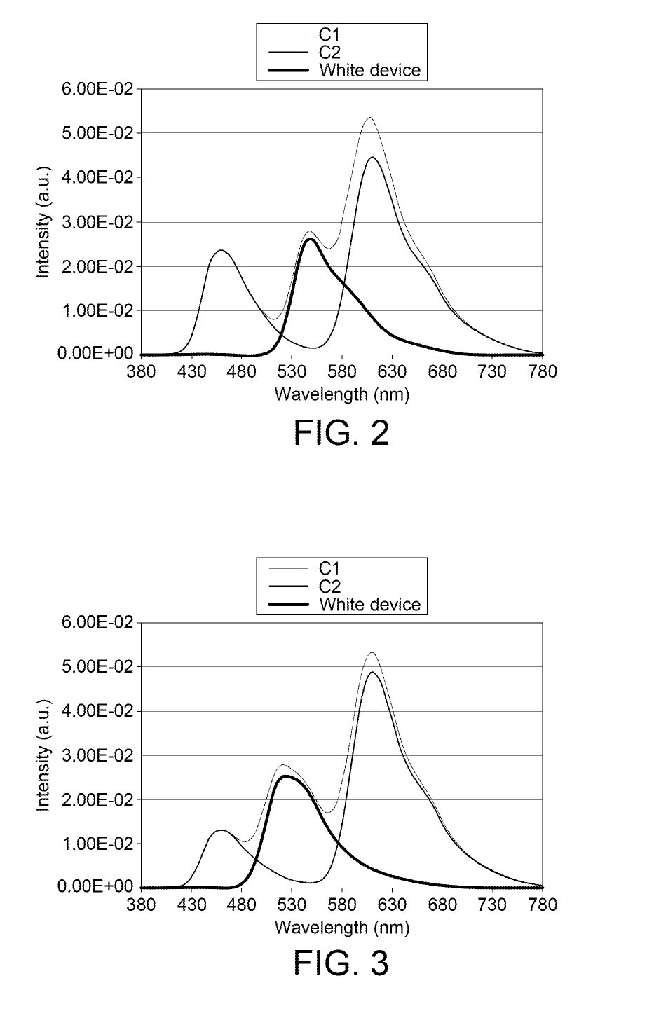

Please also refer to FIG. 1. An organic light emitting device is constructed by setting the light emitting layer 125 (emitting the first light) of the first organic electroluminescent cell C1 having a main peak of about 460 nm (blue light) with a FWHM of about 66 nm, the light emitting layer 135 (emitting the second light) of the first organic electroluminescent cell C1 having a main peak of about 610 nm (red light) with a FWHM of about 65 nm, and the light emitting layer 165 (emitting the third light) of the second organic electroluminescent cell C2 having a main peak of about 548 nm (yellow light) with a FWHM of about 62 nm. The related values are summarized in Table 1. FIG. 2 is a graph of electroluminescence spectra of the first organic electroluminescent cell C1 (represented by the Curve C1), the second organic electroluminescent cell C2 (represented by the Curve C2) and the white OLED (i.e. combination of three lights, represented by the Curve White device) of the Example 1-1. With this device, a white OLED with a good color rendering index (CRI) of 85 can be achieved. Also, the white OLED with high luminous efficiency can be obtained by the use of the light emitting layer 125 (emitting the blue light) comprising the fluorescent emitting element while the light emitting layers 135 (emitting the red light) and 165 (emitting the yellow light) comprising the phosphorescent emitting elements.

TABLE 1

| CRI: 85 | Main Peak (nm) | FWHM (nm) |
|---|---|---|
| Blue Light | 460 | 66 |
| Yellow Light | 548 | 62 |
| Red Light | 610 | 65 |

### EXAMPLE 1-2

Please also refer to FIG. 1. An organic light emitting device is constructed by setting the light emitting layer 125 (emitting the first light) of the first organic electroluminescent cell C1 having a main peak of about 460 nm (blue light) with a FWHM of about 66 nm, the light emitting layer 135 (emitting the second light) of the first organic electroluminescent cell C1 having a main peak of about 610 nm (red light) with a FWHM of about 65 nm, and the light emitting layer 165 (emitting the third light) of the second organic electroluminescent cell C2 having a main peak of about 524 nm (green light) with a FWHM of about 66 nm. The related values are summarized in Table 2. FIG. 3 is a graph of electroluminescence spectra of the first organic electroluminescent cell C1, the second organic electroluminescent cell C2 and the white OLED (i.e. combination of three lights) of the Example 1-2. With this device, a white OLED with a good color rendering index (CRI) of 85 can be achieved. Similarly, the white OLED with high luminous efficiency can be obtained by the use of the light emitting layer 125 (emitting the blue light) comprising the fluorescent emitting element while the light emitting layers 135 (emitting the red light) and 165 (emitting the green light) comprising the phosphorescent emitting elements.

TABLE 2

| CRI: 85 | Main Peak (nm) | FWHM (nm) |
|---|---|---|
| Blue Light | 460 | 66 |
| Green Light | 524 | 66 |
| Red Light | 610 | 65 |

Although the presented numerical values of wavelength ranges and FWHM of the lights show some ideal combinations for the white light organic light emitting devices with good optical properties, the disclosure is not limited thereto. The actual values of wavelength ranges and FWHM of the lights can vary significantly by modification, and be useful and capable of producing light with high optical properties under some circumstances.

The organic light emitting device of the first embodiment as shown in FIG. 1 illustrates that the first organic electroluminescent cell C1 (ex: emitting blue light and red light) is formed on the first electrode 110, and the second organic electroluminescent cell C2 (ex: emitting yellow to green light) is stacked on the first organic electroluminescent cell C1 via the CGL 150, but the present disclosure is not limited to this configuration. In other embodiments, the second organic electroluminescent cell C2 can be formed on the first electrode 110, while the first organic electroluminescent cell C1 is stacked on the second organic electroluminescent cell C2, depending on the design requirements of the practical application.

According to the embodiments, a white OLED with a good Ra equal to or larger than 85 can be achieved by providing the light emitting layer 125 (emitting the blue light), the light emitting layer 135 (emitting the red light) and the light emitting layer 165 (emitting the green light) in accordance with the ranges of the main peaks and FWHM values as listed in Table 3.

TABLE 3

| CRI: 85 | Main peak (nm) | FWHM (nm) |
|---|---|---|
| Blue | 430 < Main peak < 490 | FWHM > 55 |
| Green(yellow) | 520 < Main peak < 550 | FWHM > 66 |
| Red | 602 < Main peak < 615 | FWHM > 65 |

### Second Embodiment

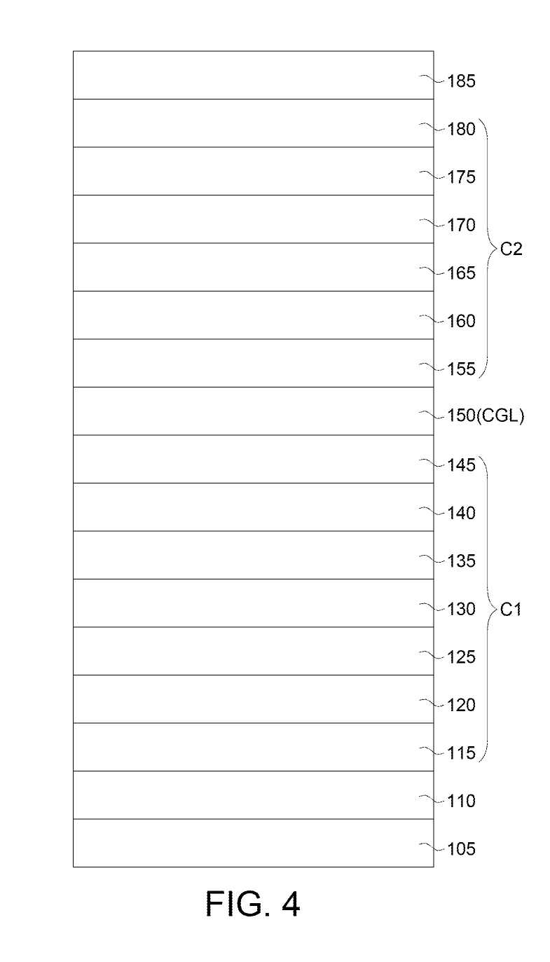

FIG. 4 illustrates a schematic cross-sectional view of an organic light emitting device according to the second embodiment of the disclosure. Structure exemplified for the organic light emitting device of the second embodiment is identical to that of the first embodiment, except for the second organic electroluminescent cell C2 comprising an additional light emitting layer 170.

Identical elements of the second and the first embodiments are designated with the same reference numerals. Some details of the elements, such as the substrate 105, the first electrode 110, the second electrode 185, the HILs 115 and 155, the HTLs 120 and 160, the light emitting layers 125 and 135, the carrier blocking layer 130, the ETLs 140 and 175, the EILs 145 and 180, and the CGL 150 have been described in the first embodiment, and are not redundantly repeated herein.

In the second embodiment, a second organic electroluminescent cell C2 having two light emitting layers emitting lights with different colors (i.e. different wavelengths in two visible light spectrum areas) is exemplified for illustration. The second organic electroluminescent cell C2 comprises a light emitting layer 165 emitting the third light with the third range of wavelengths and a light emitting layer 170 emitting a fourth light with a fourth range of wavelengths. In one embodiment, the fourth range of wavelengths is different from the third range of wavelengths.

Also, in some embodiments, one of the light emitting layers 165 and 170 may emit a light with a range of wavelengths overlapping, partially or entirely, with one of the first range of wavelengths of the first light (emitted from the light emitting layer 125) and second range of wavelengths of the second light (emitted from the light emitting layer 135).

For example, for one organic light emitting device of the second embodiment, the first light emitted from the light emitting layer 125 (cell C1) has a main peak in a range of wavelengths substantially from 430 nm to 490 nm (ex: blue light), the second light emitted from the light emitting layer 135 has a main peak in a range of wavelengths substantially from 602 nm to 615 nm (ex: red light), while the third light emitted from the light emitting layer 165 (cell C2) has a main peak in a range of wavelengths substantially from 520 nm to 550 nm (ex: yellow to green light), and the fourth light emitted from the light emitting layer 170 has a main peak in a range of wavelengths substantially from 602 nm to 615 nm (ex: red light).

In one embodiment, a full width at half maximum (FWHM) of a main peak of the first light is larger than 55 nm, a FWHM of a main peak of the second light is equal to or larger than 65 nm, a FWHM of a main peak of the third light is equal to or larger than 66 nm, and a FWHM of a main peak of the fourth light is equal to or larger than 65 nm. Corporations of the adequate main peaks and FWHM values of the first to fourth lights contribute good color with high Ra for illumination.

It is noted that those FWHM values and ranges of wavelengths of the first to fourth lights are merely for illustration, and can be adjusted and varied, such as considering the correlation and combination of the respective light colors in application to meet the requirements of the practical application, so as for obtaining an organic light emitting device with high luminous efficiency and high color rendering index. The color rendering index (Ra or CIE) of the light emitted from the organic light emitting device of the second embodiment is at least larger than 80.

### EXAMPLE 2-1

Please also refer to FIG. 4. An organic light emitting device is constructed by setting the light emitting layer 125 of the first organic electroluminescent cell C1 having a main peak of about 470 nm (emitting the blue light) with a FWHM of about 55 nm, the light emitting layer 135 of the first organic electroluminescent cell C1 having a main peak of about 606 nm (red light) with a FWHM of about 69 nm, the light emitting layer 165 of the second organic electroluminescent cell C2 having a main peak of about 548 nm (yellow light) with a FWHM of about 66 nm, and the light emitting layer 170 of the second organic electroluminescent cell C2 having a main peak of about 606 nm (red light) with a FWHM of about 69 nm. Also, this white OLED with high luminous efficiency can be obtained by the use of the light emitting layer 125 (emitting the blue light) comprising the fluorescent emitting element while the light emitting layers 135 and 170 (emitting the red light) and 165 (emitting the yellow light) comprising the respective phosphorescent emitting elements.

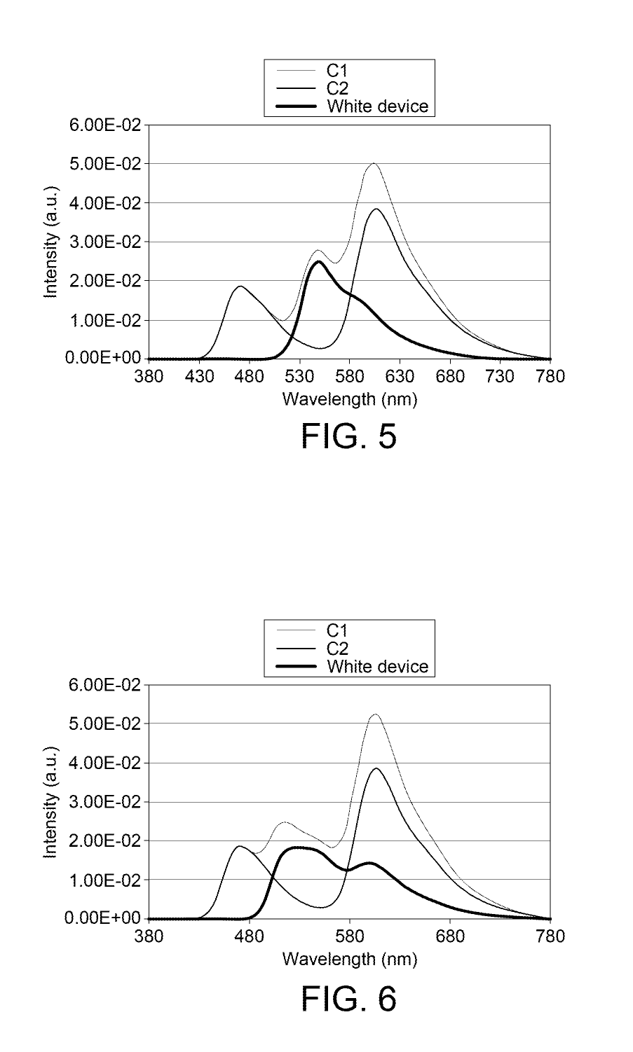

FIG. 5 is a graph of electroluminescence spectra of the first organic electroluminescent cell C1 (represented by the Curve C1), the second organic electroluminescent cell C2 (represented by the Curve C2) and the white OLED (i.e. combination of four lights, represented by the White device) of the Example 2-1. With this device, a white OLED with a good color rendering index can be achieved. Table 4 lists the generation color rendering index of Ra, and also other color rendering indexes of R9˜R14 of the white OLED of the Example 2-1. It is noted that not only the generation color rendering index is more than 80, but other color rendering indexes have been improved. For example, the R9 of the OLED is typically a negative value, but the R9 of the embodied OLED is up to 5.4, which is larger than 0. The related values of Ra and R9˜R14 of the white OLED of the Example 2-1 are summarized in Table 4.

TABLE 4

| Ra | R9 | R10 | R11 | R12 | R13 | R14 |
|---|---|---|---|---|---|---|
| 81.3 | 5.4 | 93.8 | 79.6 | 75.3 | 95.5 | 92.7 |

### EXAMPLE 2-2

Please also refer to FIG. 4. Structure of an organic light emitting device (OLED) of Example 2-2 is identical to that of Example 2-1, except for the light emitting layer 165 of the OLED of Example 2-2 having a main peak of about 524 nm (green light). The light emitting layer 165 of the OLED of Example 2-2 also comprises the phosphorescent emitting element.

FIG. 6 is a graph of electroluminescence spectra of the first organic electroluminescent cell C1 (represented by the Curve C1), the second organic electroluminescent cell C2 (represented by the Curve C2) and the white OLED (i.e. combination of four lights, represented by the White device) of the Example 2-2. With this device, a white OLED with a good color rendering index can be achieved. Table 5 lists the generation color rendering index of Ra, and also other color rendering indexes of R9-R14 of the white OLED of the Example 2-2. It is noted that not only the generation color rendering index is more than 80, but other color rendering indexes have been improved. The R9 of the embodied OLED is up to 23.7, which is a positive value (far away from 0). The related values of Ra and R9-R14 of the white OLED of the Example 2-2 are summarized in Table 5.

TABLE 5

| Ra | R9 | R10 | R11 | R12 | R13 | R14 |
|---|---|---|---|---|---|---|
| 81.6 | 23.7 | 71.6 | 86.7 | 62.2 | 92.2 | 86.8 |

Although an OLED having two organic electroluminescent cells are exemplified in the first and second embodiments, the present disclosure is not limited thereto. Other embodiments of the OLEDs constructed by three, four or more organic electroluminescent cells are also applicable. Similarly, a CGL can be provided between adjacent organic electroluminescent cells for providing efficient electron and hole injection as the connectors of the adjacent cells. In one embodiment of the OLED having three organic electroluminescent cells, one of the cells may comprise two light emitting layers (i.e. 2 colored lights), while the other two cells may comprise respective one light emitting layer (i.e. 1 colored light+1 colored light), so that the OLED emits a white light from a combination of four colored lights. Similarly, if an OLED emitting a white light from a combination of five colored lights is designed in the application, the five light emitting layers can be divided into two groups (i.e. 2 light emitting layers+3 light emitting layers) and formed in two organic electroluminescent cells, respectively. Alternatively, the five light emitting layers can be divided into four groups (i.e. 2+1+1+1 light emitting layers) and formed in four organic electroluminescent cells, respectively. Thus, the number of the organic electroluminescent cells of the OLED is not particularly limited herein, and can be varied without departing from the spirit of the disclosure to meet the requirements of the practical applications.

Also, the organic light emitting device of the embodiment can be designed, by acquiring the matched optical properties of the first and second organic electroluminescent cells, to meet the requirements of the practical application such as achieving a target color temperature. Please also refer to FIG. 1 for the configuration of an organic light emitting device of the embodiment, and the constructive details are not redundantly repeated herein. In one application of an organic light emitting device (such as a tandem OLED) with color rendering index Ra larger than 80, if a target color temperature of the organic light emitting device is determined as X, the first organic electroluminescent cell C1 has a first color temperature A and a color rendering index Ra larger than 40, and the second organic electroluminescent cell C2 has a second color temperature larger than (2X-A), wherein an electroluminescence spectrum of the second organic electroluminescent cell C2 can be complementary to an electroluminescence spectrum of the first organic electroluminescent cell C1. Take a lighting device applied by an embodied OLED with a target color temperature of 3000K (X)(warm white light) and a color rendering index Ra larger than 80 as an example, the first color temperature (A) of the first organic electroluminescent cell C1 is 1950K (less than 2000K) and the color rendering index Ra of C1 is larger than 40, while the second color temperature (2X-A) of the second organic electroluminescent cell C2 is 4050K (=2*3000−1950), wherein the electroluminescence spectra of the first and second organic electroluminescent cells C1 and C2 are complementary.

According to the aforementioned descriptions, an organic light emitting device at least comprising two organic electroluminescent cells connected by a charge generation layer is provided. In the embodiment, the light emitting layers of the OLED emitting the complementary colored lights such as the red light, the blue light and the yellow or green light, with adequate main peaks in respective wavelength ranges and the FWHM thereof, are individually formed in at least two organic electroluminescent cells of the OLED (such as a tandem OLED). Also, in one embodiment, one of the organic electroluminescent cells of the OLED at least comprises a fluorescent light emitting layer and a phosphorescent light emitting layer. The fluorescent light emitting layer may comprise blue fluorescent light emitting element, while the phosphorescent light emitting layer may comprise green or red fluorescent light emitting element. The first organic electroluminescent cell of the OLED of the embodiment possesses the ability to efficiently utilize both singlet (ex: blue light) and triplet excitons (ex: green or red light) and has higher efficiency. Also, the second organic electroluminescent cell of the OLED of the embodiment can be designed by forming the light emitting element emitting the light with color complementary to that of the first organic electroluminescent cell, so that all of the excitons of the entire OLED can be efficiently utilized. Thus, it is achievable for the OLED of the embodiment to reconcile the needs for high luminous efficiency and high color rendering index. Accordingly, the OLED of the embodiment possesses good optical properties with high color rendering index and high luminous efficiency, which meet the performance requirements of the lighting apparatus in the applications. In the embodiments, the color rendering index, Ra or CRI, of the OLED, is more than 80, and R9˜R14 have been significantly improved as well. Additionally, the overall structure is simple and easy to be fabricated, which is suitable for mass production. Thus, the OLED of the embodiment is suitable for the application of the commercial lighting apparatus requiring high optical qualities.

It will be apparent to those skilled in the art that various modifications and variations can be made to the disclosed embodiments. It is intended that the specification and examples be considered as exemplary only, with a true scope of the disclosure being indicated by the following claims and their equivalents.

1. An organic light emitting device, comprising:
a first organic electroluminescent cell, comprising a fluorescent light emitting layer having a fluorescent emitting element and a phosphorescent light emitting layer having a phosphorescent emitting element, wherein the fluorescent light emitting layer of the first organic electroluminescent cell emits a first light with a first range of wavelengths substantially from 430 nm to 490 nm and a full width at half maximum (FWHM) of a main peak is larger than 55 nm, while the phosphorescent light emitting layer of the first organic electroluminescent cell emits a second light with a second range of wavelengths substantially from 602 nm to 615 nm and a FWHM of the main peak is larger than 65 nm;
a second organic electroluminescent cell, spaced apart from the first organic electroluminescent cell, and the second organic electroluminescent cell comprising at least one light emitting layer, wherein the light emitting layer of the second organic electroluminescent cell emits a third light with a third range of wavelengths substantially from 520 nm to 550 nm and a FWHM of the main peak is larger than 66 nm;
a charge generation layer, disposed between the first and second organic electroluminescent cells; and
a first electrode and a second electrode formed at the first and second organic electroluminescent cells.

2. The organic light emitting device according to claim 1, having color rendering index Ra larger than 80.

3. (canceled)

4. The organic light emitting device according to claim 1, wherein the second organic electroluminescent cell comprises at least two said light emitting layers for emitting two lights with different wavelengths in two visible light spectrum areas, and one of said light emitting layers emits light with a range of wavelengths overlapping with one of the first and second ranges of wavelengths.

5. The organic light emitting device according to claim 1, wherein the light emitting layer of the second organic electroluminescent cell comprises a fluorescent emitting element.

6. The organic light emitting device according to claim 1, wherein the light emitting layer of the second organic electroluminescent cell comprises a phosphorescent emitting element.

7. The organic light emitting device according to claim 1, wherein the fluorescent light emitting layer and the phosphorescent light emitting layer of the first organic electroluminescent cell are separated by a carrier blocking layer.

8. The organic light emitting device according to claim 1, wherein the first electrode is formed on a substrate, and the first organic electroluminescent cell is formed on the first electrode, while the second electrode is formed on the second organic electroluminescent cell, wherein the first electrode and the second electrode are an anode and a cathode, respectively.

9. The organic light emitting device according to claim 1, wherein the first electrode is formed on a substrate, and the second organic electroluminescent cell is formed on the first electrode, while the second electrode is formed on the first organic electroluminescent cell, wherein the first electrode and the second electrode are an anode and a cathode, respectively.

10. An organic light emitting device, comprising:
a first organic electroluminescent cell, comprising at least two light emitting layers emitting a first light with a first range of wavelengths, and a second light with a second range of wavelengths, wherein the first light has a main peak in a range of wavelengths substantially from 430 nm to 490 nm and a full width at half maximum (FWHM) of the main peak of the first light is larger than 55 nm, and the second light has a main peak in a range of wavelengths substantially from 602 nm to 615 nm and a FWHM of the main peak of the second light is equal to or larger than 65 nm;
a second organic electroluminescent cell, spaced apart from the first organic electroluminescent cell, and the second organic electroluminescent cell comprising at least one light emitting layer emitting a third light with a third range of wavelengths, wherein the third light has a main peak in a range of wavelengths substantially from 520 nm to 550 nm, and a FWHM of the main peak of the third light is equal to or larger than 66 nm;
a charge generation layer, disposed between the first and second organic electroluminescent cells; and
a first electrode and a second electrode formed at the first and second organic electroluminescent cells.

11. The organic light emitting device according to claim 10, having color rendering index Ra larger than 80.

12. (canceled)

13. The organic light emitting device according to claim 10, wherein the second organic electroluminescent cell comprises at least two light emitting layers emitting two light with different wavelengths in two visible light spectrum areas, and one of said light emitting layers emits light with a range of wavelengths overlapping with one of the first and second ranges of wavelengths.

14. The organic light emitting device according to claim 10, wherein the first electrode is formed on a substrate, and the first organic electroluminescent cell is formed on the first electrode, while the second electrode is formed on the second organic electroluminescent cell, wherein the first electrode and the second electrode are an anode and a cathode, respectively.

15. The organic light emitting device according to claim 10, wherein the first electrode is formed on a substrate, and the second organic electroluminescent cell is formed on the first electrode, while the second electrode is formed on the first organic electroluminescent cell, wherein the first electrode and the second electrode are an anode and a cathode, respectively.

16. The organic light emitting device according to claim 10, wherein said two light emitting layers of the first organic electroluminescent cell are a fluorescent light emitting layer having a fluorescent emitting element and a phosphorescent light emitting layer having a phosphorescent emitting element.

17. The organic light emitting device according to claim 16, wherein the fluorescent light emitting layer and the phosphorescent light emitting layer of the first organic electroluminescent cell are separated by a carrier blocking layer.

18. The organic light emitting device according to claim 16, wherein the light emitting layer of the second organic electroluminescent cell comprises a fluorescent emitting element.

19. The organic light emitting device according to claim 16, wherein the light emitting layer of the second organic electroluminescent cell comprises a phosphorescent emitting element.

20. An organic light emitting device with color rendering index Ra larger than 80, comprising:
a first organic electroluminescent cell, comprising a fluorescent light emitting layer having a fluorescent emitting element and a phosphorescent light emitting layer having a phosphorescent emitting element, wherein the first organic electroluminescent cell has a first color temperature A in a range of 1800K-3000K and a color rendering index Ra larger than 40;
a second organic electroluminescent cell, spaced apart from the first organic electroluminescent cell, and the second organic electroluminescent cell comprising at least one light emitting layer, wherein the second organic electroluminescent cell has a second color temperature larger than (2X-A), and X is a target color temperature of the organic light emitting device, wherein said X is in a range of 3000K-6000K;
a charge generation layer, disposed between the first and second organic electroluminescent cells; and
a first electrode and a second electrode formed at the first and second organic electroluminescent cells,
wherein electroluminescence spectrum of the second organic electroluminescent cell is complementary to electroluminescence spectrum of the first organic electroluminescent cell.

21. The organic light emitting device according to claim 20, wherein the first organic electroluminescent cell has color rendering index R9 larger than 30.

22. The organic light emitting device according to claim 20, wherein the fluorescent light emitting layer of the first organic electroluminescent cell emits a first light with a first range of wavelengths substantially from 430 nm to 490 nm and a full width at half maximum (FWHM) of the main peak is larger than 55 nm, while the phosphorescent light emitting layer of the first organic electroluminescent cell emit a second light with a second range of wavelengths substantially from 602 nm to 615 nm and a FWHM of the main peak is larger than 65 nm, and the first range of wavelengths is different from the second range of wavelengths.

23. The organic light emitting device according to claim 20, wherein the light emitting layer of the second organic electroluminescent cell emit a third light with a third range of wavelengths substantially from 520 nm to 550 nm and a FWHM of the main peak is larger than 66 nm, and the third range of wavelengths is different from the first range of wavelengths and also different from the second range of wavelengths.

24. The organic light emitting device according to claim 20, wherein the second organic electroluminescent cell comprises at least two said light emitting layers for emitting two lights with different wavelengths in two visible light spectrum areas, and one of said light emitting layers emits light with a range of wavelengths overlapping with one of the first and second ranges of wavelengths.

25. The organic light emitting device according to claim 20, wherein the light emitting layer of the second organic electroluminescent cell comprises a fluorescent emitting element.

26. The organic light emitting device according to claim 20, wherein the light emitting layer of the second organic electroluminescent cell comprises a phosphorescent emitting element.

27. The organic light emitting device according to claim 20, wherein the fluorescent light emitting layer and the phosphorescent light emitting layer of the first organic electroluminescent cell are separated by a carrier blocking layer.

28. The organic light emitting device according to claim 20, wherein the first electrode is formed on a substrate, and the first organic electroluminescent cell is formed on the first electrode, while the second electrode is formed on the second organic electroluminescent cell, wherein the first electrode and the second electrode are an anode and a cathode, respectively.

29. The organic light emitting device according to claim 20, wherein the first electrode is formed on a substrate, and the second organic electroluminescent cell is formed on the first electrode, while the second electrode is formed on the first organic electroluminescent cell, wherein the first electrode and the second electrode are an anode and a cathode, respectively.
